(19) United States
(12) Patent Application Publication
(10) Pub. No.: US 2018/0004091 A1
(43) Pub. Date: Jan. 4, 2018

(54) MOLD, IMPRINTING METHOD, IMPRINT APPARATUS, AND METHOD FOR MANUFACTURING A SEMICONDUCTOR ARTICLE

(71) Applicant: CANON KABUSHIKI KAISHA, Tokyo (JP)

(72) Inventor: Ken-ichiro Shinoda, Utsunomiya-shi (JP)

(21) Appl. No.: 15/630,600

(22) Filed: Jun. 22, 2017

(30) Foreign Application Priority Data
Jun. 30, 2016 (JP) 2016-130918

(51) Int. Cl. G03F 7/20

(52) U.S. Cl. CPC G03F 7/2014

(57) ABSTRACT

A mold used for an imprint apparatus, including a pattern portion where a pattern is formed, and a peripheral portion surrounding the pattern portion, wherein the peripheral portion is provided with a light-shielding portion that blocks curing light for curing an imprint material and transmits detection light for detecting a detection target.

### BACKGROUND

### Field of the Disclosure

The present disclosure relates to a mold, an imprinting method, an imprint apparatus, and a method for manufacturing an article.

### Description of the Related Art

In an imprinting technique for manufacturing a semiconductor device and the like, a mold on which a pattern is formed is brought into contact with an imprint material supplied on a substrate, and light is emitted thereon to cure the imprint material, thereby forming a pattern of the imprint material on the substrate. There is known a method in which, when the imprint material is supplied on the substrate, the imprint material is supplied on the entire surface of the substrate or on a plurality of shot areas on the substrate.

After a pattern portion of the mold is brought into contact with the imprint material supplied on the substrate, the light is emitted onto the substrate through the mold to cure the imprint material. In this case, a light irradiated region needs to be accurately controlled to prevent a shot area adjacent to a shot area immediately below the pattern portion from being irradiated with the light.

Japanese Patent Application Laid-Open No. 2015-12034 discusses a method for accurately controlling the irradiated region. According to Japanese Patent Application Laid-Open No. 2015-12034, a mold is provided with a light-shielding portion in such a manner that the light-shielding portion is provided on a recess of the mold where a thickness of the mold is small, to surround a pattern portion. Further, Japanese Patent Application Laid-Open No. 2015-204399 discusses a mold provided with a light-shielding portion that is provided on a lower surface of the mold to surround a pattern portion.

Meanwhile, in an imprint apparatus discussed in Japanese Patent Application Laid-Open No. 2015-130384, mold alignment is performed by using a mold side mark and a fiducial mark. The mold side mark is provided on an outer side of a pattern portion of a mold. The fiducial mark is provided on a fiducial plate below an area on the outer side of the pattern portion of the mold.

The light-shielding portion for controlling the irradiated region, as discussed in Japanese Patent Application Laid-Open No. 2015-12034 or in Japanese Patent Application Laid-Open No. 2015-204399, has been unable to be provided in the configuration discussed in Japanese Patent Application Laid-Open No. 2015-130384 in which the fiducial mark below the area on the outer side of the pattern portion of the mold is detected through the mold. Further, the light-shielding portion for controlling the irradiated region, as discussed in Japanese Patent Application Laid-Open No. 2015-12034 or in Japanese Patent Application Laid-Open No. 2015-204399, has been unable to be provided to a mold in a case where an imprint material in an adjacent shot area below the area on the outer side of the pattern portion of the mold is desired to be detected.

### SUMMARY

According to an aspect of the present disclosure, a mold used for an imprint apparatus includes a pattern portion where a pattern is formed, and a peripheral portion surrounding the pattern portion, wherein the peripheral portion is provided with a light-shielding portion that blocks curing light for curing an imprint material and transmits detection light for detecting a detection target.

Further features of the present disclosure will become apparent from the following description of exemplary embodiments with reference to the attached drawings.

### BRIEF DESCRIPTION OF THE DRAWINGS

FIG. 1 is a diagram illustrating an imprint apparatus according to one exemplary embodiment.

FIG. 2 is a diagram illustrating an aligning process using a fiducial mark according to one exemplary embodiment.

FIG. 3 is a diagram illustrating a mold according to one exemplary embodiment.

FIG. 4 is a flowchart illustrating an imprinting process according to one exemplary embodiment.

FIGS. 5A and 5B are each a diagram illustrating an imprinting process using a conventional mold.

FIG. 6 is a graph illustrating transmittances of light-shielding portions according to one exemplary embodiment.

FIGS. 7A, 7B, and 7C are each a diagram illustrating a mold provided with a light-shielding portion according to one example.

FIGS. 8A and 8B are each a diagram illustrating a mold provided with a light-shielding portion according to another example.

FIGS. 9A and 9B are each a diagram illustrating a light-shielding portion according to another exemplary embodiment.

FIG. 10 is a graph illustrating characteristics (extinction coefficients) of light-shielding films.

FIGS. 11A, 11B, 11C, 11D, 11E, and 11F are diagrams illustrating methods for manufacturing an article.

### DESCRIPTION OF THE EMBODIMENTS

Exemplary embodiments of the present disclosure are described in detail below with reference to the attached drawings. In the drawings, the same components are denoted with the same reference numerals, and a redundant description thereof is omitted.

### (Imprint Apparatus)

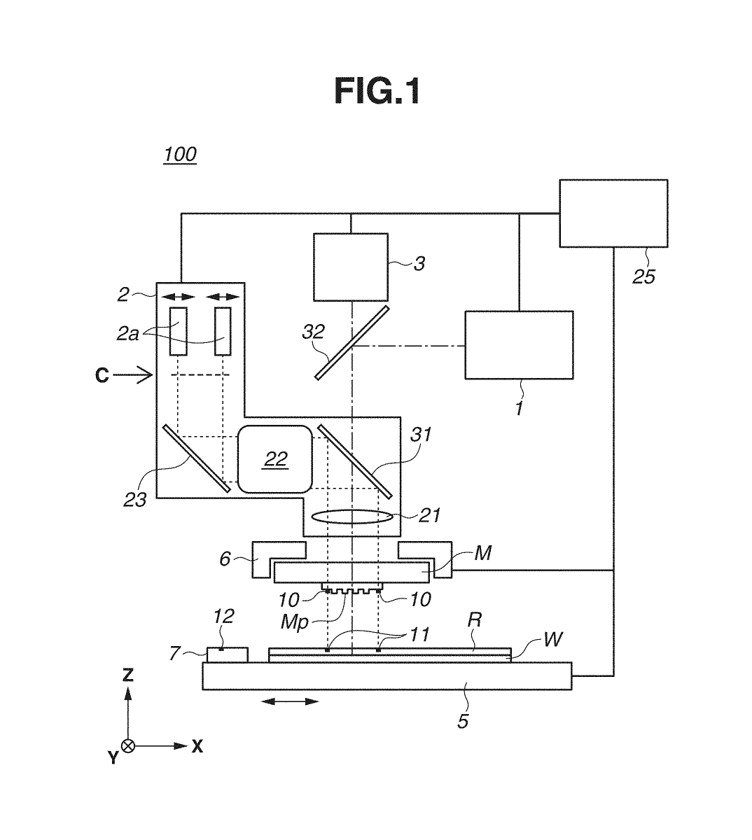

First, a configuration of an imprint apparatus 100 according to a first exemplary embodiment of the present disclosure is described. FIG. 1 is a diagram illustrating the configuration of the imprint apparatus 100 according to the present exemplary embodiment. The imprint apparatus 100 forms a pattern of a cured material onto which a recess and protrusion pattern of a mold has been transferred by bringing an imprint material supplied on a substrate into contact with the mold, and applying curing energy to the imprint material. The imprint apparatus 100 is used for manufacturing devices such as a semiconductor device, and forms a pattern on an imprint material R on a substrate W to be processed by using a mold M. The imprint apparatus 100 according to the first exemplary embodiment employs a photo-curing method in which the imprint material is irradiated with light to be cured. The description is given below with reference to the drawings in which directions orthogonal to each other within planes of the substrate W and the mold M are defined as an X axis direction and a Y axis direction, and a direction orthogonal to the X axis direction and the Y axis direction is defined as a Z axis direction.

The imprint apparatus 100 includes an illumination system 1, an alignment optical system 2, an observing optical system 3, a substrate stage 5 (substrate holding unit) that holds the substrate W, a mold holding unit 6 that holds the mold M, and a control unit 25 that controls an operation of each component of the imprint apparatus 100.

A predetermined three-dimensional pattern Mp (for example, a recess and protrusion pattern such as a circuit pattern) is formed on a surface of the mold M facing the substrate W. The mold M is made of a material (such as quartz) capable of transmitting light (for example, ultraviolet light) for curing the imprint material. The substrate W is, for example, a substrate made of monocrystalline silicon, and has a processed surface entirely coated with an imprint material R before the imprinting process is performed. A coating device, outside the imprint apparatus 100, is in charge of coating the substrate W with the imprint material R. However, this should not be construed in a limiting sense. For example, a coating unit configured to perform the coating using the imprint material R may be provided in the imprint apparatus 100. Thus, the entire surface of the substrate may be coated with the imprint material R in advance by the coating unit, before the imprinting process is performed. An area of the substrate coated with the imprint material is not limited to the entire surface. For example, a plurality of shot areas (pattern forming areas) may be coated at once, or the shot areas may be coated one by one.

A curing composition (also referred to as uncured resin) that is cured upon receiving curing energy is used as the imprint material R. The curing energy includes electromagnetic waves, heat, and the like. Examples of the electromagnetic waves include light, such as infrared light, visible light, and ultraviolet light, with a wavelength selected in a range of 10 nm inclusive to 1 mm inclusive.

The curing composition is cured upon being irradiated with light or heated. The curing composition includes a photocuring composition cured by light. The photocuring composition, which is cured by light, at least includes a polymerizable compound and a photopolymerization initiator, and may further include a non-polymerizable compound or a solvent as appropriate. The non-polymerizable compound is at least one type selected from the group consisting of a sensitizer, a hydrogen donor, an internal release agent, a surfactant, an antioxidant, and a polymer component.

The imprint material R in a form of a film is provided on the substrate with a spin coater or a slit coater. Alternatively, a liquid discharging head may be used to provide the imprint material R in a form of droplets, or in an island-shaped manner or in the form of a film with a plurality of droplets connected to each other on the substrate. The imprint material has a viscosity (at 25° C.) equal to or higher than 1 mPa·s and equal to or lower than 100 mPa·s.

The substrate W may be made of glass, ceramics, metal, semiconductor, resin, or the like. When required, a member made of a material different from that of the substrate may be formed on a surface of the substrate W. Specific examples of the substrate W include a silicon wafer, a compound semiconductor wafer, and a quartz glass wafer.

For example, the substrate stage 5 holds the substrate W with vacuum suction force or electrostatic force. The substrate stage 5 includes a substrate chuck that holds the substrate W, and a substrate driving mechanism that moves the substrate W in a direction along an XY plane. The substrate stage 5 is provided with a stage reference plate 7 on which a fiducial mark 12 (detection target) of the imprint apparatus 100 is formed.

For example, the mold holding unit 6 holds the mold M with vacuum suction force or electrostatic force. The mold holding unit 6 includes a mold chuck that holds the mold M, and a mold driving mechanism that moves the mold chuck in the Z axis direction so that the mold M can be pressed against the imprint material on the substrate W. The mold holding unit 6 may further include a mold deforming mechanism that deforms the mold M (pattern Mp) in the X and Y axis directions. For example, mold pressing and releasing processes in the imprint apparatus 100 may be implemented with the mold M, the substrate stage 5 (the substrate W), or both moving in the Z axis direction.

The illumination system 1 emits the curing light (ultraviolet light) for curing the imprint material R, after the mold pressing process with which the mold M and the imprint material R on the substrate W are brought in contact with each other. The illumination system 1 includes a light source and a plurality of optical elements with which the pattern Mp of the mold M that has an area of a predetermined shape, as the processed surface, is uniformly irradiated with ultraviolet light from the light source. Preferably, the area of the illumination system 1 irradiated with light (irradiated area) is substantially the same as an area (pattern portion) where the pattern Mp is formed. This is because the minimum possible irradiated area thus set can achieve the lowest risk of displacement or distortion of the pattern to be transferred onto the imprint material R, due to expansion of the mold M or the substrate W by heat involved in the light irradiation. Examples of the light source that can be used include a high pressure mercury lamp, various excimer lamps, excimer laser, a light emitting diode, and a laser diode. While the light source of the illumination system 1 is selected as appropriate in accordance with the characteristics of the imprint material as a light receiving member, the present disclosure is not limited by the type, quantity, wavelengths, or the like of the light source.

The alignment optical system 2 is in charge of measurement for aligning the mold M and the substrate W with each other. The alignment optical system 2 optically detects a mold side mark 10 formed on the mold M and a substrate side mark 11 formed on the substrate W to measure relative position between the mold M and the substrate W. The alignment optical system 2 further optically detects the mold side mark 10 of the mold M and the fiducial mark 12 on the stage reference plate 7 to measure the relative position between the mold M and the stage reference plate 7. The mold side mark 10 of the mold M and the fiducial mark 12 of the imprint apparatus 100 may be detected to measure the position of the mold M relative to the imprint apparatus 100.

The alignment optical system 2 includes a plurality of photoreception units 2a forming a scope that can be driven. The photoreception units 2a can be driven in the X axis direction and in the Y axis direction, in accordance with the position of the mold side mark 10 or the substrate side mark 11. For example, when fiducial marks 12 are formed at positions of the stage reference plate 7 corresponding to four corners of the pattern portion on which the pattern Mp is formed, the shape of the pattern portion of the mold M can be measured. Furthermore, the photoreception units 2a can be driven also in the Z axis direction, so that the scope can be focused at the position of the mark. Optical members (21, 22, 23, and 31) form a relay optical system, with a plane, conjugated to the plane of the substrate W, formed at a position C.

The substrate W includes multilayers formed of various materials, and the substrate side mark 11 of the substrate W is generally formed on any one of the multilayers. Thus, when the wavelength bandwidth of light emitted from the alignment optical system 2 is narrow, the light might have a wavelength under a condition resulting in a destructive interference. As a result, a signal from the substrate side mark 11 of the substrate W becomes weak, rendering the alignment difficult.

Thus, the light used for the alignment optical system 2 preferably has a wavelength in a widest possible wavelength bandwidth causing no curing (exposing) of the imprint material R. For example, the wavelength bandwidth of the light used in the alignment optical system 2 is 400 to 2000 nm, and is at least 500 to 800 nm. For example, a lamp featuring a wide wavelength bandwidth may be used as the light source used in the alignment optical system 2. Alternatively, a wide wavelength bandwidth may be covered with a combination of a plurality of light sources (light emitting diodes, laser diodes, or the like) each emitting light in a wavelength bandwidth of several tens of nanometer or several nanometers.

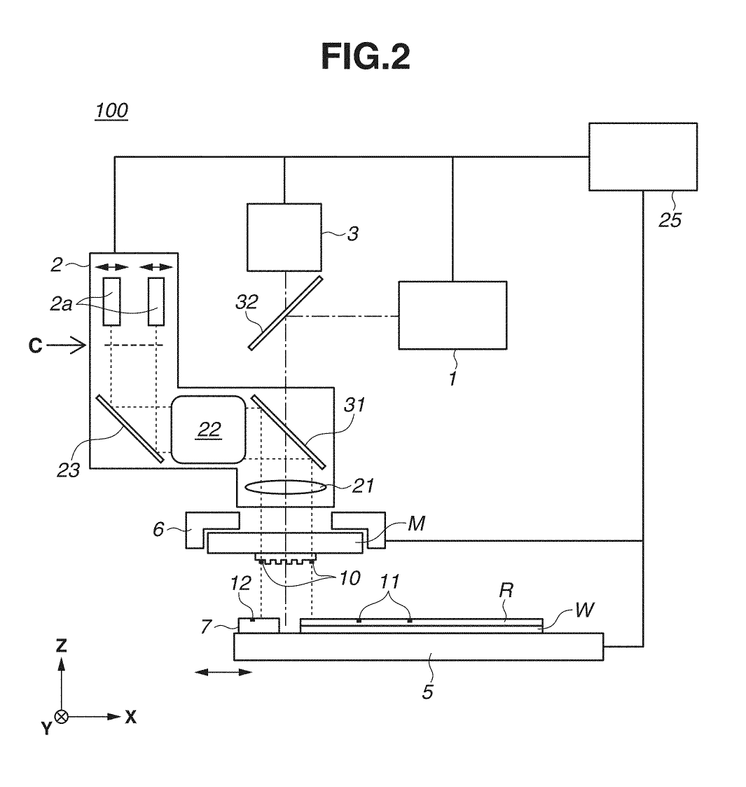

The control unit 25 controls the substrate stage 5, the mold holding unit 6, and the mold deforming mechanism based on information on the relative position between the mold M and the substrate W measured by the alignment optical system 2. When the mold M is replaced or in other like cases, the relative position is adjusted with the mold side mark 10 and the fiducial mark 12 detected as illustrated in FIG. 2. With this adjustment, the shot area where the imprinting is performed when the substrate W is carried in and the mold M can be in the field of view of the alignment optical system 2. Thus, the shot area and the mold M can be aligned with each other. Furthermore, the shape of the pattern portion on the mold M can be corrected.

The observing optical system 3 is an image capturing system (camera) that captures an image of the entire shot area of the substrate W, and is used for detecting a status of the imprinting process (imprint material). A detection target of the observing optical system 3 includes the imprint material on the substrate and an alignment mark for the alignment. The status of the imprinting process to be detected includes a status of filling the mold M with the imprint material R and a status of releasing the mold M from the imprint material R. The measurement target of the observing optical system 3 is the imprint material on the substrate or the pattern Mp of the mold M or the surface of the substrate W, or may be the surface of the pattern Mp and the surface of the substrate W in a case where the mold M and the substrate W are close to each other. The field of view of the observing optical system 3 is wider than the area of the pattern Mp. Thus, a shot area adjacent to the shot area on which the pattern is formed can be observed, and a status of the imprint material in the periphery of the shot area can be detected. In a peripheral area around the pattern Mp, no pattern is formed, and thus the status of the substrate W and the imprint material R can be observed through the mold M. Thus, a mark or the imprint material may be detected through the mold M in the peripheral area around the pattern Mp.

Observing light (detection light) used in the observing optical system 3 does not need to have a wavelength bandwidth as wide as that of the light used in the alignment optical system 2, and any wavelength may be employed as long as the imprint material R is not cured (exposed). The detection light of the observing optical system 3 involves heat, which may deform the mold M or the substrate W. Thus, the observing light is preferably set to be as weak as possible, without compromising the observing performance, to prevent the displacement and distortion of the pattern formed on the imprint material R.

In the imprint apparatus 100, common optical members 21 and 31 are formed that have functions related to each of the illumination system 1, the alignment optical system 2, and the observing optical system 3. The common optical member 31 has a function of reflecting the light from the alignment optical system 2 and transmitting the curing light from the illumination system 1 and the observing light from the observing optical system 3. The common optical members 21 and 31 are each formed of a material (such as quartz or fluorite) featuring a sufficiently high transmittance against ultraviolet light as the curing light.

An example of the common optical member 31 includes a dichroic mirror featuring a high reflectance against light with a wavelength bandwidth in a range of 500 to 2000 nm and a high transmittance against light with a wavelength bandwidth in a range of 200 to 500 nm. The wavelength bandwidth covered by a high reflectance is not limited to the range of 500 to 2000 nm, and is preferably as wide as possible. Practically, the range may be 600 to 900 nm or 500 to 800 nm due to restriction in manufacturing. Similarly, the wavelength bandwidth of the light covered by a high transmittance is not limited to the range of 200 to 500 nm, and is preferably as wide as possible. Practically, the range may be 300 to 600 nm or 300 to 500 nm for example.

The optical member 32 has a function of reflecting the curing light from the illumination system 1, and transmitting the detection light from the observing optical system 3. For example, the optical member 32 is a dichroic mirror featuring a high reflectance for light with a wavelength that is not longer than 400 nm (200 to 400 nm or 300 to 400 nm), and a high transmittance for light with a wavelength not shorter than 400 nm (400 to 500 nm or 400 to 600 nm). However, the threshold is not limited to 400 nm, and may be 380 nm or 420 nm. As described above, in the imprint apparatus 100 according to the first exemplary embodiment, the wavelength bandwidth of the curing light from the illumination system 1 is in an ultraviolet range. The wavelength bandwidth of the alignment light (detection light) from the alignment optical system 2 is wider than that of the curing light. The wavelength bandwidth of the observing light from the observing optical system 3 is between those of the curing light and the alignment light.

The configuration described above can provide an imprint apparatus that can use all of the curing light with a wavelength suitable for curing the imprint material, the alignment light requiring a wide wavelength bandwidth, and the observing light for observing the shot area.

### (Mold)

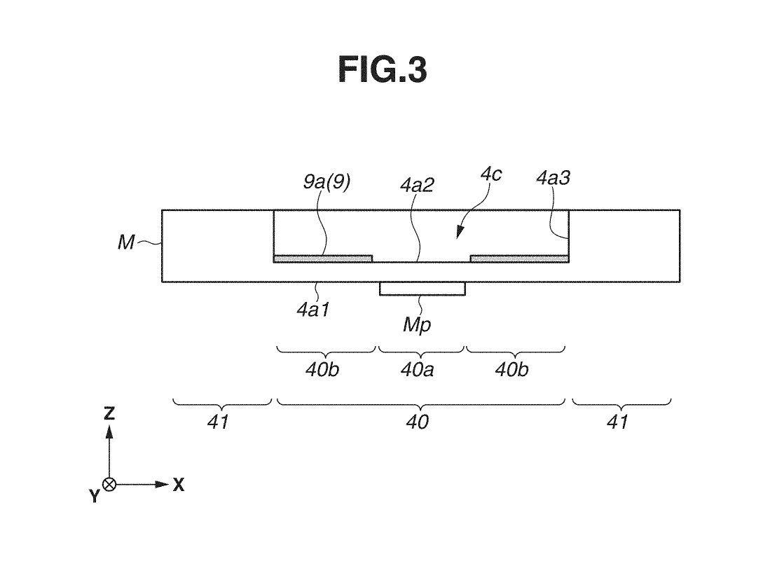

FIG. 3 is a cross-sectional view of the mold M according to the first exemplary embodiment. The mold M includes a first portion 40 and a second portion 41. The first portion 40 includes a first surface 4a1 and a second surface 4a2 opposite to the first surface 4a1. The first surface includes a pattern portion 40a (mesa portion) provided with the pattern Mp and a peripheral portion 40b (off-mesa portion) surrounding the pattern portion 40a. The mold M has a larger thickness (length in the Z axis direction) in the second portion 41, surrounding the first portion 40, than the first portion 40. The pattern portion 40a (mesa portion) has a form (protruding form) protruding toward the substrate W. The pattern portion 40a may be provided with a scribe line surrounding the pattern Mp. In many cases, the mold side mark 10 used for aligning the mold M is formed on the scribe line. The pattern portion of the mold M according to the present exemplary embodiment includes the pattern Mp and the scribe line. In the mold M having the configuration described above, a recess 4c (cavity, core out) is formed by the second surface 4a2 of the first portion 40 and a third surface 4a3 on the inner side of the second portion 41. With the recess 4c thus formed in the mold M, the first portion 40 (first surface 4a1) of the mold M can be easily deformed by changing the pressure (for example, atmospheric pressure) in the recess 4c.

### (Imprinting Process)

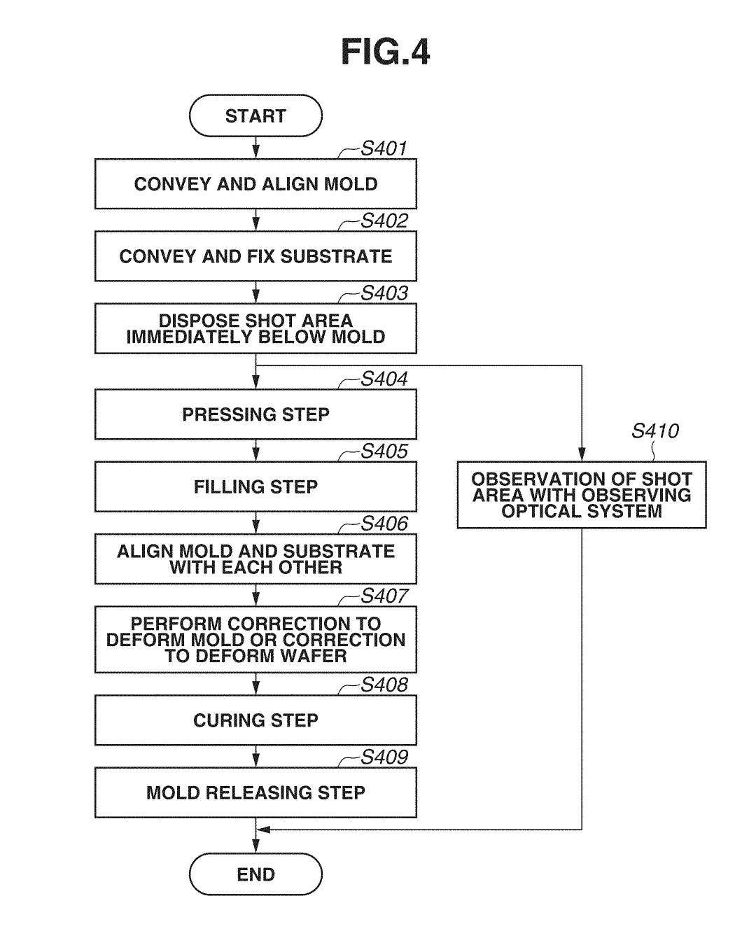

Next, the imprinting process executed by the imprint apparatus 100 is described with reference to FIG. 4. When the imprinting process starts, in step S401, the mold M according to the first exemplary embodiment is conveyed into the imprint apparatus 100 to be held by the mold holding unit 6. In this process, the photoreception unit 2a of the alignment optical system 2 detects the mold side mark 10 and the fiducial mark 12, in the state illustrated in FIG. 2, and thus the mold M is aligned with respect to the substrate stage 5. The fiducial mark 12 of the stage reference plate 7 is detected through the mold M, and thus is difficult to detect in a portion including the pattern of the mold M. Thus, the fiducial mark 12 is formed at a position that can be detected through the off-mesa portion (40b in FIG. 3) where no pattern or mark is formed.

Next, in step S402, the substrate W is conveyed by a substrate conveyance unit (not illustrated) into the imprint apparatus 100 to be held by the substrate stage 5. In step S403, the substrate stage 5 is moved in such a manner that the shot area (pattern forming area) formed on the substrate W is disposed (positioned) immediately below the pattern Mp of the mold M. More specifically, the imprinting process is performed one by one on the plurality of shot areas in the substrate W having the entire surface coated with the imprint material R in advance. As described above, in the case described in the first exemplary embodiment, the imprint material R is supplied on the entire surface of the substrate W in advance. Alternatively, the imprint material R may be supplied on the shot areas in the imprint apparatus 100 through a supplying (coating) step performed between step S402 and S403.

Then, in step S404, the driving mechanism of the mold holding unit 6 is driven to bring the mold M into contact with the imprint material R on the substrate W (pressing step). In step S405, the imprint material R in contact with the mold M flows along the recess and protrusion pattern as the pattern Mp formed on the mold M (filling step). The alignment optical system 2 detects the mold side mark 10 and the substrate side mark 11 while the mold M and the imprint material R are in contact with each other. In step S406, the substrate stage 5 is driven based on the detection result of the alignment optical system 2 to align the substrate W and the mold M with each other. In step S407, the mold deforming mechanism may perform correction to deform the mold M (shot areas) or the substrate W may be heated to perform correction to deform the shot area, based on the detection result of the alignment optical system 2.

After the mold M and the substrate W are aligned with each other, in step S408, the illumination system 1 irradiates the imprint material R with ultraviolet light from the back surface (upper surface) of the mold M, to cure the imprint material R (curing step). After the imprint material R has been cured, in step S409, the driving mechanism of the mold holding unit 6 is driven to release the mold M from the cured imprint material R (mold releasing step). When the mold M is released from the imprint material R, the pattern of the imprint material R is formed on the shot areas of the substrate W. Thus, the pattern Mp in the recess and protrusion form formed on the mold M is transferred onto the substrate W. The imprinting process according to the first exemplary embodiment may include step S410 as at least a part of processing between the pressing step in step S404 and the mold releasing step in step S409. In step S410, the observing optical system 3 can observe the pattern portion. The observing optical system 3 can perform the observation to check whether an abnormality has occurred within the detection field of view, in each step of the imprinting process.

The imprinting process according to the first exemplary embodiment is performed one by one on the plurality of shot areas in the substrate W having the entire surface coated with the imprint material R in advance.

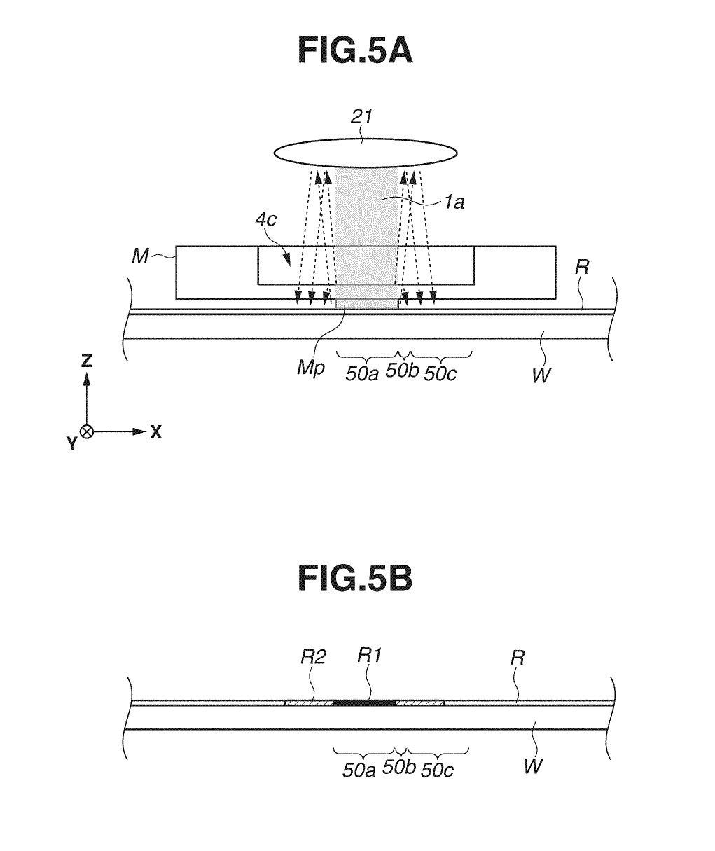

As illustrated in FIG. 5A, the curing light (a grey portion in the figure) emitted onto the shot area 50a, while the pattern Mp and the imprint material R are in contact with each other, is reflected on the surfaces of the substrate W and the mold M. The curing light thus reflected is reflected again on the mold M or the common optical member 21 in the imprint apparatus (dotted lines in the figure). Thus, light (also referred to as flare light) might reach a peripheral area 50b around the shot area 50a of the substrate W.

As a result, as illustrated in FIG. 5B, not only the imprint material R supplied on the shot area 50a but also the imprint material R coated on the peripheral area 50b around the shot area 50a and on an adjacent shot area 50c might be cured. For example, FIG. 5B illustrates a state where an imprint material R1 supplied on the shot area 50a is cured, and an imprint material R2 coated on the peripheral area 50b and the adjacent shot area 50c is in a semi-cured state. The peripheral area 50b is an area between two shot areas, and may be the scribe line for example. When the imprint material R in the peripheral area 50b or the adjacent shot area 50c is cured or is in the semi-cured state as described above, the imprinting process cannot be properly performed in the adjacent shot area 50c, where the imprinting is to be performed later.

In view of the above, the recess of the mold M according to the first exemplary embodiment is provided with a light-shielding portion 9 on a surface of the peripheral portion 40b (off-mesa portion) opposite to a surface facing the substrate W, as illustrated in FIG. 3. The light-shielding portion 9 is provided in the periphery of the pattern portion 40a, so that the curing light incident on the mold M can transmit through the pattern portion 40a of the pattern Mp. If the light-shielding portion 9 includes a metal film of chrome or the like, the film blocks not only the curing light (ultraviolet light) but also the alignment light and the observing light (light in the visible to infrared range), which is not preferable.

Thus, the light-shielding portion 9 according to the present disclosure has a function of blocking the curing light and transmitting the observing light or the alignment light. With this function of the light-shielding portion 9, the peripheral area 50b and the adjacent shot area 50c can be observed with the observing light, with the curing light blocked so as not to reach the peripheral area 50b and the adjacent shot area 50c. The fiducial mark 12 of the imprint apparatus 100 and the marks (alignment marks) provided on the peripheral area 50b and the adjacent shot area 50c can be detected with the curing light blocked. The light-shielding portion 9 according to the first exemplary embodiment includes a light-shielding film 9a. It is desirable that the light-shielding film 9a be made of a material capable of blocking ultraviolet light and transmitting light with a wavelength in the wavelength bandwidth corresponding to the visible to infrared range. For example, the light-shielding film 9a can be made of a material such as a dielectric multilayered film (Al₂O₃, SiO, MgF₂), metal nitrides such as CrN and TaN, and metal oxides such as Cr₂O₃ and TiO.

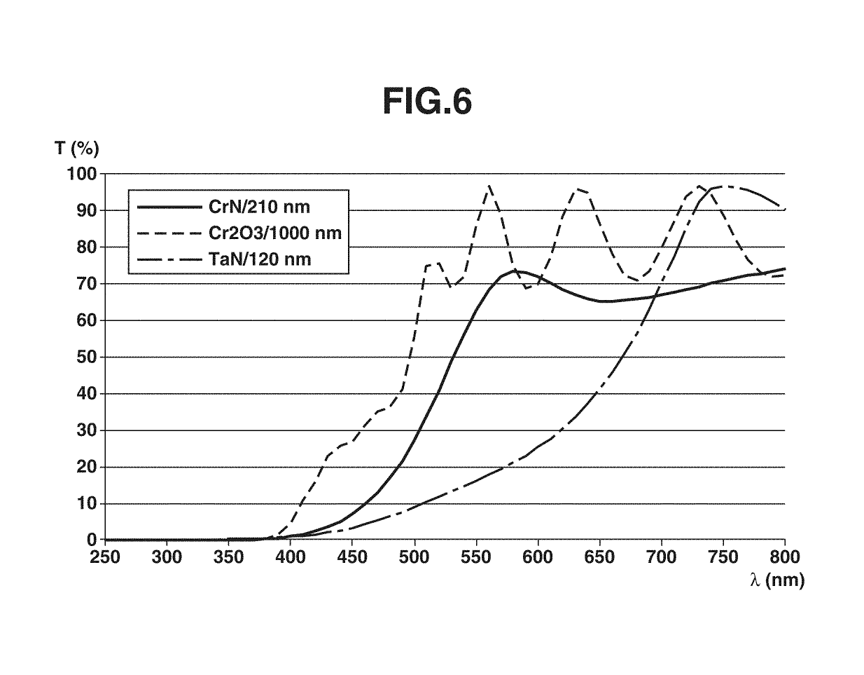

FIG. 6 illustrates spectral transmittance characteristics achieved with the light-shielding film 9a provided to the mold M. In FIG. 6, the horizontal axis represents a wavelength and the vertical axis represents a transmittance. FIG. 6 is a graph illustrating a case where the mold M is provided with, as the light-shielding film 9a, a film of CrN with a thickness of 210 nm, a case where the mold M is provided with, as the light-shielding film 9a, a film of Cr₂O₃ with a thickness of 1000 nm, and a case where the mold M is provided with, as the light-shielding film 9a, a film of TaN with a thickness of 120 nm. The transmittance characteristics required in the present disclosure feature a smallest possible transmittance for the light in the ultraviolet range (preferably a transmittance of 1% or lower for light with a wavelength of 400 nm or shorter) and a largest possible transmittance for the light in the visible to infrared range (preferably a transmittance of 10% or higher for light with a wavelength of 500 to 800 nm). It can be seen in the graph that the required thickness is different among the light-shielding films 9a made of the different materials. For example, the light-shielding film 9a features a transmittance that is equal to or higher than 0% and equal to or lower than 1% for the light in a wavelength bandwidth of 380 nm or shorter, and a transmittance of that is equal to or higher than 10% and equal to or lower than 100% for the light in a wavelength bandwidth of 500 to 800 nm.

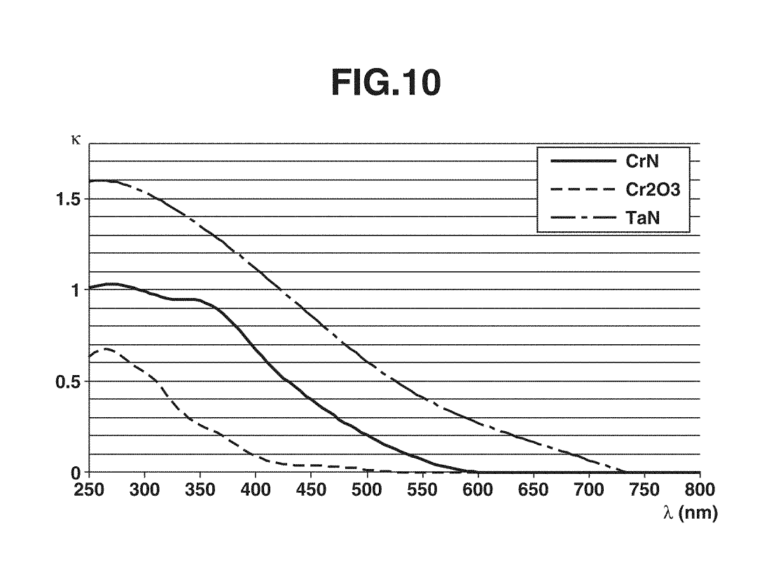

The material that can be used for the light-shielding film 9a can be determined by obtaining spectral transmittance characteristics for each material as illustrated in FIG. 6. The transmittance is highly correlated with an extinction coefficient K of each material, and thus the material that can be used as the light-shielding film 9a can be determined by obtaining the extinction coefficient K. FIG. 10 is a graph in which the vertical axis and the horizontal axis respectively represent the extinction coefficient K and the wavelength of each of the materials (CrN, Cr₂O₃, and TaN) illustrated in FIG. 6.

The extinction coefficient K of CrN is 0.67 or more for the wavelength bandwidth (for example, 300 to 400 nm) corresponding to the curing light, and is 0.21 or less for the wavelength bandwidth (for example, 500 to 800 nm) corresponding to the alignment light. Thus, the material featuring a low transmittance for the curing light and a high transmittance for the alignment light and the observing light. Similarly, the extinction coefficient K of Cr₂O₃ is 0.10 or more for the wavelength bandwidth of 300 to 400 nm, and is 0.02 or less for the wavelength bandwidth of 500 to 800 nm. Similarly, the extinction coefficient K of TaN is 1.10 or more for the wavelength bandwidth of 300 to 400 nm, and is 0.61 or less for the wavelength bandwidth of 500 to 800 nm. Thus, the materials each feature a low transmittance for the curing light and a high transmittance for the alignment light and the observing light.

Table 1 illustrates a relationship [Ka]/[Kb] where [Ka] represents the extinction coefficient K corresponding to the wavelength bandwidth of 300 to 380 nm, and [Kb] represents the extinction coefficient K corresponding to the wavelength bandwidth of 500 to 800 nm.

TABLE 1

| | [Ka] | [Kb] | [Ka]/[Kb] |
|---|---|---|---|
| Cr₂O₃ | 0.10 or more | 0.02 or less | 5.0 or more |
| CrN | 0.67 or more | 0.21 or less | 3.2 or more |
| TaN | 1.10 or more | 0.61 or less | 1.8 or more |

From the above, it is desirable that the light-shielding portion 9 be made of a material satisfying a condition that [Ka] is 0.1 or more (preferably 0.5 or more) and that [Ka]/[Kb] is 1.8 or more (preferably 3.0 or more).

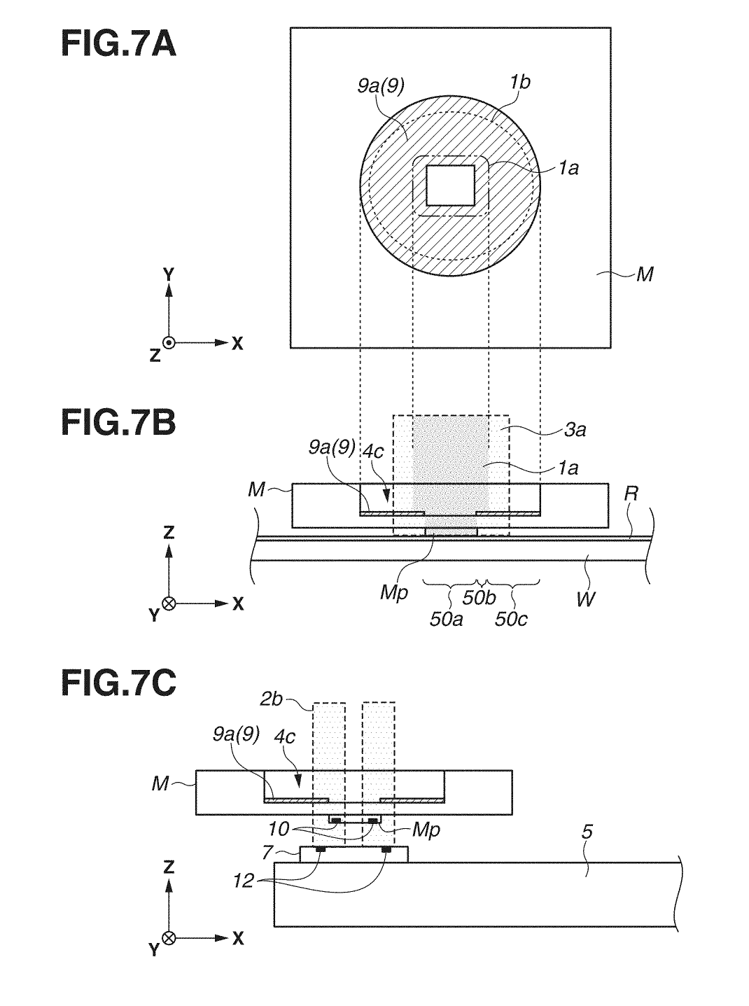

FIGS. 7A, 7B, and 7C are each a diagram illustrating a mold M provided with a light-shielding portion 9 according to a first example of the first exemplary embodiment. The mold M is used in the imprint apparatus 100. As illustrated in FIG. 7, the mold M has the second surface 4a2 provided with the light-shielding portion 9 (light-shielding film 9a) surrounding the pattern portion 40a. FIG. 7A is a diagram illustrating the mold M as viewed in the Z axis direction. The two-dot chain line in the figure represents an illumination field of view (an area irradiated with curing light 1a from the illumination system 1) of the illumination system 1. Dotted lines in the figure represents an area 1b where the flare light of the curing light 1a reaches.

FIG. 7B illustrates a state where the imprint material R on the substrate W, in contact with the mold M, is irradiated with the curing light 1a and with observing light 3a (detection light) through the mold M. The light-shielding film 9a illustrated in FIG. 7 is configured in such a manner that the curing light transmits through the pattern Mp. Curing light 1a (including the flare light) is blocked by the light-shielding film 9a so as not to reach the peripheral area 50b and the adjacent shot area 50c. The observing light 3a transmits through the light-shielding film 9a, so that the peripheral area 50b as the peripheral portion of the pattern portion 40a and the adjacent shot area 50c can be observed.

FIG. 7C is a diagram illustrating a process of aligning the mold M and the stage reference plate 7 with each other. The fiducial mark 12 of the stage reference plate 7 provided to the substrate stage 5 is disposed below the peripheral portion 40b (off-mesa portion) of the mold M where no pattern is formed. The alignment optical system 2 detects the mold side mark 10 formed on the pattern portion 40a of the mold M where the pattern Mp is formed and the fiducial mark 12 of the stage reference plate 7, by emitting alignment light 2b (detection light). The mold M and the stage reference plate 7 (fiducial mark 12) are aligned with each other based on a result of the mark detection. In this manner, the curing light 1a (flare light) is blocked by the light-shielding film 9a on the mold M so as not to reach the peripheral area 50b or the adjacent shot area 50c. The alignment light 2b and the observing light 3a transmit through the light-shielding film 9a so that the fiducial mark 12 of the imprint apparatus formed in the peripheral area 50b can be detected and the status of the adjacent shot area 50c can be observed.

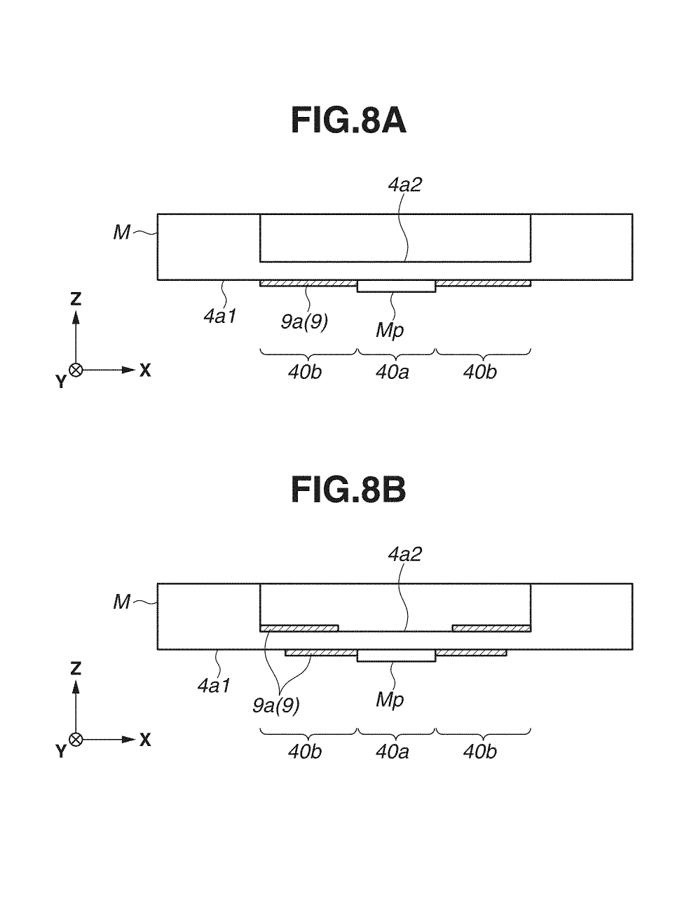

FIGS. 8A and 8B are each a diagram illustrating a mold M provided with a light-shielding portion 9 according to a second example of the first exemplary embodiment. The mold M is used in the imprint apparatus 100. As illustrated FIG. 8A, the mold M has the first surface 4a1 provided with the light-shielding portion 9 (light-shielding film 9a) surrounding the pattern portion 40a where the pattern Mp is formed. The mold M according to the first example described above has the second surface 4a2 provided with the light-shielding portion 9 (light-shielding film 9a) surrounding the pattern portion 40a. The surface of the mold M provided with the light-shielding portion 9 is not limited to the second surface 4a2, and may be the first surface 4a1 as illustrated in FIG. 8A. As illustrated in FIG. 8B, the light-shielding film 9a may be formed in areas of the first surface 4a1 and the second surface 4a2 of the mold M that correspond to the peripheral portion 40b (off-mesa portion). The light-shielding film 9a according to the second example is capable of blocking the curing light and transmitting the observing light or the alignment light as in the first example.

With the light-shielding film 9a formed on the mold M as illustrated in FIGS. 8A and 8B, the curing light is less likely to reach the periphery of the shot area. The light-shielding film 9a may be provided to the first surface 4a1 of the mold M so that the light-shielding portion 9 can be disposed closer to the surface of the substrate. Thus, the curing light emitted to obliquely travel toward the second surface 4a2 of the mold M can be blocked, so that the peripheral area 50b can be irradiated with the obliquely traveling light. Also in the second example, the curing light is blocked so as not to reach the peripheral area 50b and the alignment light 2b is transmitted. Thus, the fiducial mark of the imprint apparatus provided at the peripheral portion of the shot area 50a can be detected, and the status of the peripheral portion can be observed.

Next, an imprint apparatus according to a second exemplary embodiment is described. The light-shielding portion 9 according to the first exemplary embodiment is the light-shielding film 9a formed on the surface of the mold M. A light-shielding portion 9 according to the second exemplary embodiment is a light-shielding member 9b that can be detachably attached to the recess 4c of the mold M.

The light-shielding member 9b as the light-shielding portion 9 is described below. The imprint apparatus according to the second exemplary embodiment has a configuration other than the light-shielding portion 9 that is the same as that in the imprint apparatus 100 according to the first exemplary embodiment. Thus, the description on the configuration other than the light-shielding portion 9 is omitted herein.

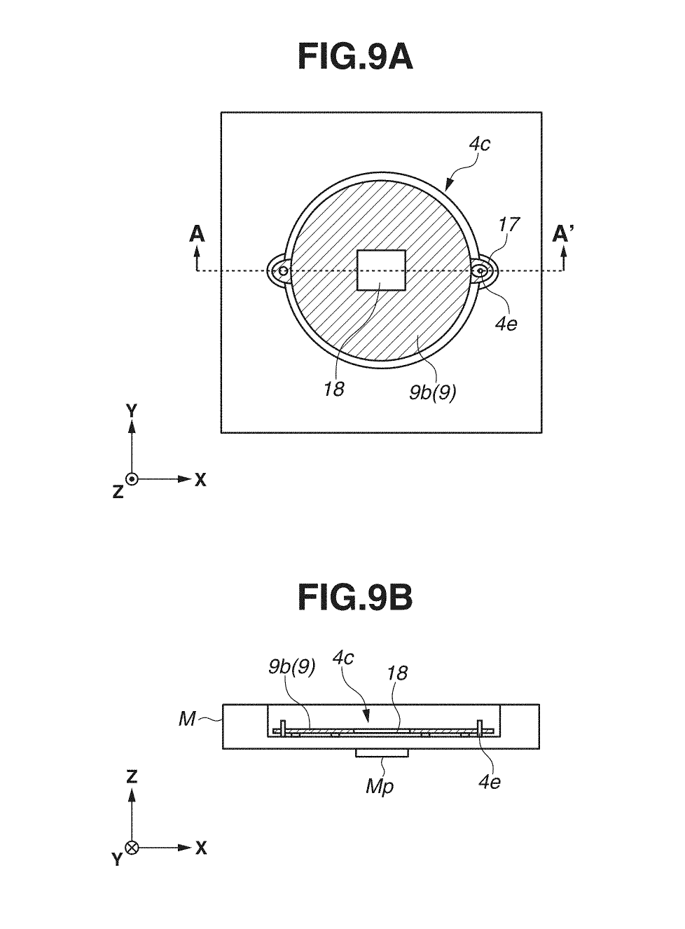

FIGS. 9A and 9B are each a diagram illustrating the mold M and the light-shielding member 9b used in the imprint apparatus according to the second exemplary embodiment. FIG. 9A is a diagram illustrating the mold M and the light-shielding member 9b as viewed in the Z axis direction. FIG. 9B is a cross-sectional view of the mold M and the light-shielding member 9b taken along line A-A′ in FIG. 9A. As described above, the light-shielding member 9b can be detached from the recess 4c of the mold M.

Through holes 17 are formed at positions of the light-shielding member 9b corresponding to pins 4e provided to the recess 4c of the mold M. The light-shielding member 9b is fixed to the mold M with the pins 4e inserted in the through holes 17. Thus, the displacement along a direction (XY direction) of a plane parallel to the surface of the substrate W, with respect to the mold M can be regulated to be within a tolerable range. With the light-shielding member 9b having the configuration described above, the displacement in the XY axis directions with respect to the mold M can be regulated to be within a range of ±5 μm for example.

The light-shielding member 9b is capable of blocking the curing light for curing the imprint material, and transmitting the observing light and the alignment light. The light-shielding member 9b is provided with an opening 18 through which the curing light passes. The curing light that has passed through the opening 18 can be emitted onto the pattern Mp (pattern portion 40a). In the imprint apparatus 100 with the light-shielding member 9b having the configuration described above, the curing light can be emitted onto the shot area 50a, on which the pattern Mp formed in the pattern portion is to be transferred, and is less likely to be emitted onto the peripheral area 50b. Furthermore, the status of the imprinting process in the peripheral area 50b and in the adjacent shot area 50c can be observed, and a mark formed outside the area corresponding to the pattern portion 40a can be detected.

The light-shielding member 9b is a member made of quartz and the like that transmit the observing light, the alignment light, and the curing light. A light-shielding film is provided on an area other than the opening 18. It is desirable that the light-shielding film be made of a material capable of blocking ultraviolet light as the curing light and transmitting visible light and infrared light as the observing light and the alignment light. For example, a dielectric multilayered film, metal nitrides such as CrN, or metal oxides such as Cr₂O₃ and TiO may be provided on the member made of quartz. The materials are not limited to these, and any material capable of blocking the curing light for curing the imprint material R and transmitting the alignment light and the observing light may be employed.

In the imprint apparatus according to the second embodiment, the light-shielding member 9b that can be detachably attached to the recess 4c of the mold M is used as the light-shielding portion 9. With the light-shielding member 9b having such a configuration used as the light-shielding portion 9, the mold M can be washed with the light-shielding member 9b detached from the mold M. Thus, there is a lower risk of the light-shielding portion 9 being peeled off from the mold M, while the mold M is being washed.

The light-shielding film 9a used as the light-shielding portion 9 in the first exemplary embodiment and the light-shielding member 9b used as the light-shielding portion 9 in the second exemplary embodiment may be used in combination.

In each of the exemplary embodiments described above, the substrate W having the entire surface coated with the imprint material R is used. However, this should not be construed in a limiting sense. Alternatively, the substrate W not coated with the imprint material R may be carried into the imprint apparatus 100. Then, a desired number of shot areas may be coated with the imprint material R by a supplying unit (dispenser) provided to the imprint apparatus 100.

The imprint material not actively supplied onto the adjacent shot area might flow beyond the shot area, on which the pattern is to be formed, to be on the adjacent shot area. Even in such a case, the pattern can be formed on the shot area without curing the imprint material on the peripheral area when the mold M according to the present disclosure is used.

### (Method for Manufacturing Article)

The pattern of the cured material formed by using the imprint apparatus is used as at least one of components of various articles, or is temporarily used for manufacturing various articles. The article includes an electric circuit element, an optical element, Micro Electronic Mechanical Systems (MEMS), a recording element, a sensor, and a mold. The electric circuit element includes a volatile or nonvolatile semiconductor memory such as a dynamic random access memory (DRAM), a static RAM (SRAM), a flash memory, a magnetic RAM (MRAM), and a semiconductor device such as a large-scale integration (LSI), a charged coupled device (CCD), an image sensor, and a field programmable gate array (FPGA). The mold includes a mold for imprinting.

The pattern of the cured member may be directly used as one of the components of the article, or may be temporarily used as a resist mask that is removed after etching or ion injection is performed as processing on a substrate.

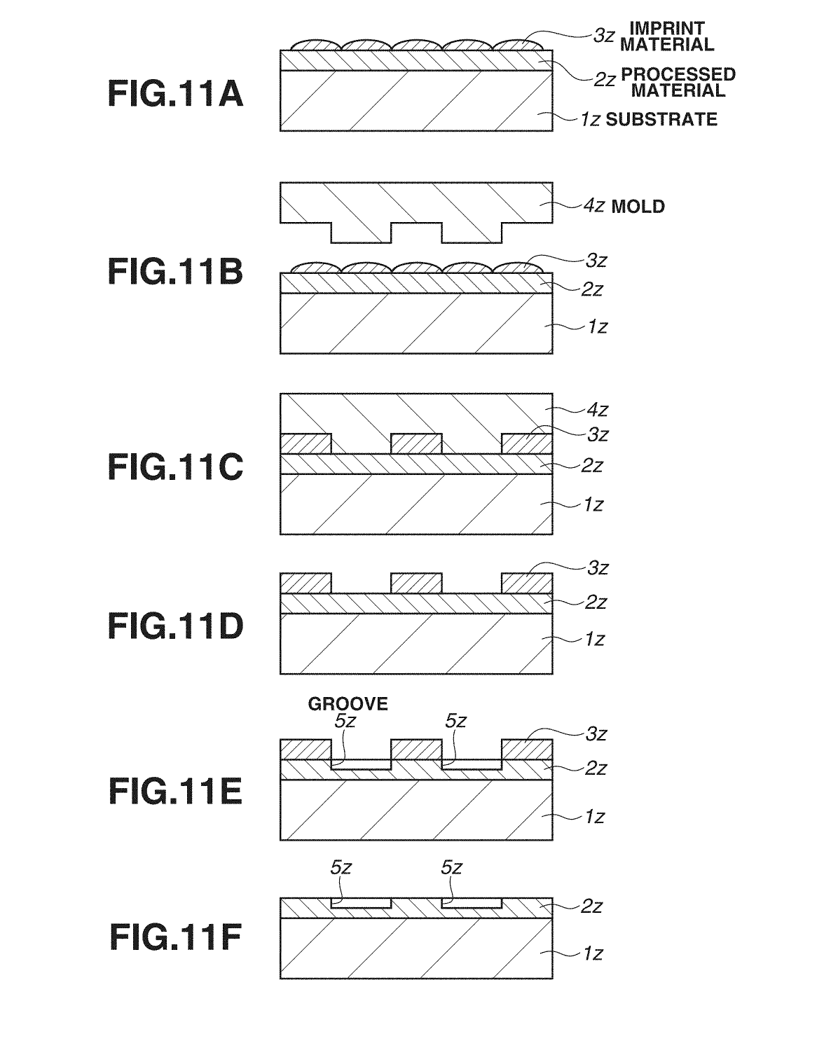

Next, a specific method for manufacturing an article is described. As illustrated in FIG. 11A, a substrate 1z, such as a silicon wafer, with a surface on which a processed material 2z such as an insulator is formed is prepared. Then, an imprint material 3z is provided on a surface of the processed material 2z with an ink-jet method or the like. The figure illustrates a state where a plurality of the imprint materials 3z in a form of droplets are provided on the substrate.

As illustrated in FIG. 11B, a mold 4z for imprinting is disposed with a side on which a recess and protrusion pattern is formed facing the imprint material 3z on the substrate 1z. As illustrate in FIG. 11C, the substrate 1z, provided with the imprint material 3z, and the mold 4z are brought into contact with each other and pressure is applied. The imprint material 3z fills a gap between the mold 4z and the processed material 2z. In this state, the imprint material 3z is curing upon being irradiated with light as curing energy through the mold 4z.

As illustrated in FIG. 11D, after the imprint material 3z has been cured, the mold 4z and the substrate 1z are released from each other, whereby a pattern of the imprint material 3z as a cured material is formed on the substrate 1z. The pattern of the cured material has a shape with protrusions corresponding to the recesses of the mold. Thus, the recess and protrusion pattern of the mold 4z is transferred onto the imprint material 3z.

As illustrated in FIG. 11E, etching is performed with the pattern of the cured material used as an etching resistant mask, whereby grooves 5z are formed at portions of the surface of the processed material 2z with no cured material or with only a thin cured material remaining. As illustrated in FIG. 11F, when the pattern of the cured material is removed, an article with the grooves 5z formed on the surface of the processed material 2z can be obtained. The pattern of the cured member removed in the case described above needs not to be removed after the process, and may be used, for example, as an interlayer insulating film in a semiconductor device and the like, that is, as a component of the article.

The present disclosure is not limited to the exemplary embodiments described above, and can be modified and changed in various ways without departing from the innovation provided in the present disclosure.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2016-130918, filed Jun. 30, 2016, which is hereby incorporated by reference in its entirety.

What is claimed is:

1. A mold used for an imprint apparatus, the mold comprising:
a pattern portion where a pattern is formed; and
a peripheral portion surrounding the pattern portion,
wherein the peripheral portion is provided with a light-shielding portion that blocks curing light for curing an imprint material and transmits detection light for detecting a detection target.

2. The mold according to claim 1, wherein the light-shielding portion has a transmittance that is equal to or higher than 0% and equal to or lower than 1% for a wavelength bandwidth corresponding to the curing light and a transmittance that is equal to or higher than 10% and equal to or lower than 100% for a wavelength bandwidth corresponding to the detection light.

3. The mold according to claim 1, wherein the light-shielding portion is provided on a surface opposite to a surface on which the pattern portion is formed.

4. The mold according to claim 1, wherein the light-shielding portion is provided on a surface on which the pattern portion is formed.

5. The mold according to claim 1, wherein the light-shielding portion is provided on a surface opposite to a surface on which the pattern portion is formed and a surface on which the pattern portion is formed.

6. The mold according to claim 1, wherein the light-shielding portion includes a light-shielding film provided on a surface of the mold.

7. The mold according to claim 1,
wherein the light-shielding portion is a light-shielding member attached to the mold, and
wherein the light-shielding member is obtained by attaching a light-shielding film that blocks the curing light and transmits the detection light on a surface of a member that transmits the curing light.

8. The mold according to claim 1, wherein the light-shielding portion includes a light-shielding film containing CrN.

9. The mold according to claim 1, wherein the light-shielding portion includes a light-shielding film formed of a dielectric multilayered film.

10. The mold according to claim 1, wherein the detection target includes a fiducial mark of the imprint apparatus.

11. The mold according to claim 1, wherein the detection target includes an imprint material supplied on a substrate.

12. The mold according to claim 1, wherein the light-shielding portion transmits detection light for detecting an imprint material in an area corresponding to the peripheral portion when the pattern portion of the mold is brought into contact with the imprint material on a substrate.

13. The mold according to claim 1, wherein the light-shielding portion blocks ultraviolet light as the curing light and transmits visible light or infrared light as the detection light.

14. An imprinting method for forming a pattern on an imprint material supplied on a substrate, by using a mold that includes a pattern portion where a pattern is formed and a peripheral portion surrounding the pattern portion, the peripheral portion being provided with a light-shielding portion, the imprinting method comprising:
aligning the mold and the substrate with each other; and
bringing the mold into contact with the imprint material and curing the imprint material,
wherein the light-shielding portion blocks curing light for curing the imprint material and transmits detection light for detecting a detection target.

15. An imprint apparatus configured to form a pattern of an imprint material on a substrate, by using a mold,
wherein the mold includes a pattern portion where a pattern to be transferred onto the imprint material is formed, and a peripheral portion surrounding the pattern portion, and
wherein the peripheral portion is provided with a light-shielding portion that blocks curing light for curing the imprint material and transmits detection light for detecting a detection target.

16. A method for manufacturing an article, the method comprising:
forming a pattern of an imprint material on a substrate by an imprinting method; and
processing the substrate on which the pattern has been formed in the forming,
wherein the imprinting method is an imprinting method for forming a pattern of an imprint material on a substrate, by using a mold that includes a pattern portion where a pattern is formed and a peripheral portion surrounding the pattern portion, the peripheral portion being provided with a light-shielding portion, and includes:
aligning the mold and the substrate with each other; and
bringing the mold into contact with the imprint material and curing the imprint material,
wherein the light-shielding portion blocks curing light for curing the imprint material and transmits detection light for detecting a detection target, and
wherein an article is manufactured with the substrate that has been processed in the processing.
